(19) United States
(12) Patent Application Publication
(10) Pub. No.: US 2025/0324707 A1
(43) Pub. Date: Oct. 16, 2025

(54) SEMICONDUCTOR STRUCTURE AND METHOD OF FORMING THE SAME

(71) Applicant: HON HAI PRECISION INDUSTRY CO., LTD., New Taipei City (TW)

(72) Inventors: Jheng-Sheng YOU, New Taipei City (TW); Hung-Yu CHEN, New Taipei City (TW); Wen-Yuan HSIEH, New Taipei City (TW)

(21) Appl. No.: 18/676,472

(22) Filed: May 28, 2024

(30) Foreign Application Priority Data
Apr. 10, 2024 (TW) 113113249

(51) Int. Cl. H01L 29/40; H01L 21/768; H01L 29/423

(52) U.S. Cl. CPC H10D 64/111; H01L 21/76829; H10D 64/514

(57) ABSTRACT

A semiconductor structure includes a gate structure on a semiconductor layer on a substrate; a first dielectric layer continuously extending on the gate structure and the semiconductor layer and including a third portion and a fourth portion on an upper surface of the gate structure, a first portion, and a second portion; a second dielectric layer on an etch stop layer on at least the first portion and the fourth portion; and a field-plate. The field-plate includes a first field-plate portion and a fourth field-plate portion on the second dielectric layer and includes a second field-plate portion and a third field-plate portion on the second portion and the fourth portion, respectively. Lower surfaces of the first field-plate portion and the fourth field-plate portion are farther away from the semiconductor layer compared to lower surfaces of the second field-plate portion and the third field-plate portion, respectively.

### CROSS-REFERENCE TO RELATED APPLICATION

This application claims priority to Taiwan Application Serial Number 113113249, filed Apr. 10, 2024, incorporated herein by reference in its entirety.

### BACKGROUND

### Field of Invention

The disclosure relates to a semiconductor structure and a method of forming the same.

### Description of Related Art

Power semiconductor devices continue to develop and are widely used in applications, e.g., wireless communications, electronics, and electric vehicles. However, components that can withstand high power should have high breakdown voltages, and better devices should have high electron mobility, good thermal stability, etc. Therefore, a novel semiconductor structure and a method of forming the same are required to continue developing the field.

### SUMMARY

The disclosure provides a semiconductor structure including a gate structure on a semiconductor layer on a substrate, a first dielectric layer, an etch stop layer, a second dielectric layer on the etch stop layer, and a field plate. The first dielectric layer extends continuously on the gate structure and the semiconductor layer and includes a first portion, a second portion, a third portion, and a fourth portion. The third portion and the fourth portion are on an upper surface of the gate structure. The etch stop layer is on at least the first portion and the fourth portion of the first dielectric layer. The field plate includes a first field plate portion on the second dielectric layer, a second field plate portion and a third field plate portion respectively on the second portion and the third portion of the first dielectric layer, and a fourth field plate portion on the second dielectric layer. A first distance between a lower surface of the first field plate portion and the semiconductor layer is larger than a second distance between a lower surface of the second field plate portion and the semiconductor layer, and a third distance between a lower surface of the third field plate portion and the semiconductor layer is smaller than a fourth distance between a lower surface of the fourth field plate portion and the semiconductor layer.

The disclosure provides a method of forming a semiconductor structure. A gate structure is formed on a semiconductor layer on a substrate. A first dielectric layer is formed on the gate structure and the semiconductor layer. An etch stop layer is formed on the first dielectric layer. A second dielectric layer is formed on the etch stop layer, in which the etch stop layer separates the second dielectric layer from the first dielectric layer. A portion of the second dielectric layer is etched to make an etching depth at least reach an upper surface of the etch stop layer to form an opening in a remaining portion of the second dielectric layer, in which a portion of an upper surface of the gate structure and a side surface of the gate structure connected to the portion of the upper surface of the gate structure are under the opening. A field plate is formed on the second dielectric layer and the opening.

### BRIEF DESCRIPTION OF THE DRAWINGS

FIGS. 1A to 1D are schematic diagrams of the semiconductor structure according to some embodiments of the disclosure.

FIGS. 2 to 4 are schematic diagrams of the structures during the intermediate stages of the method of forming the semiconductor structure according to some embodiments of the disclosure.

### DETAILED DESCRIPTION

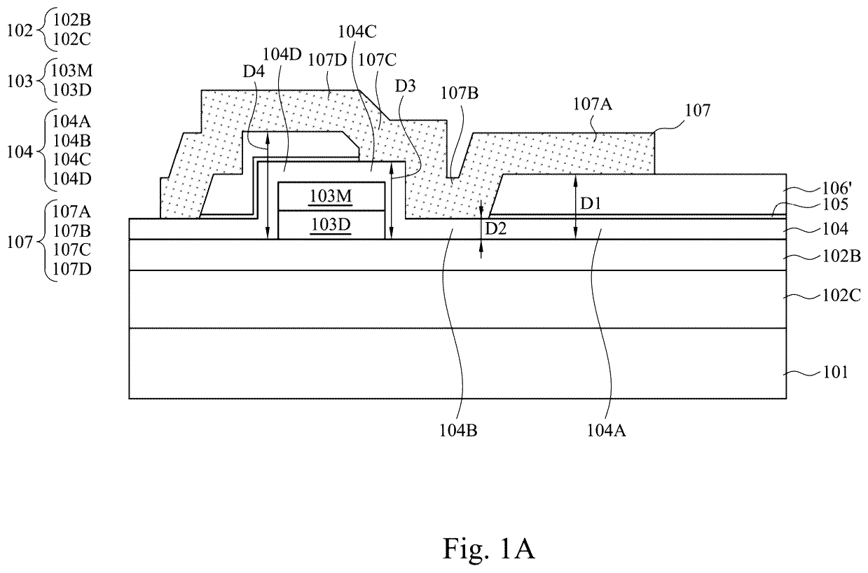

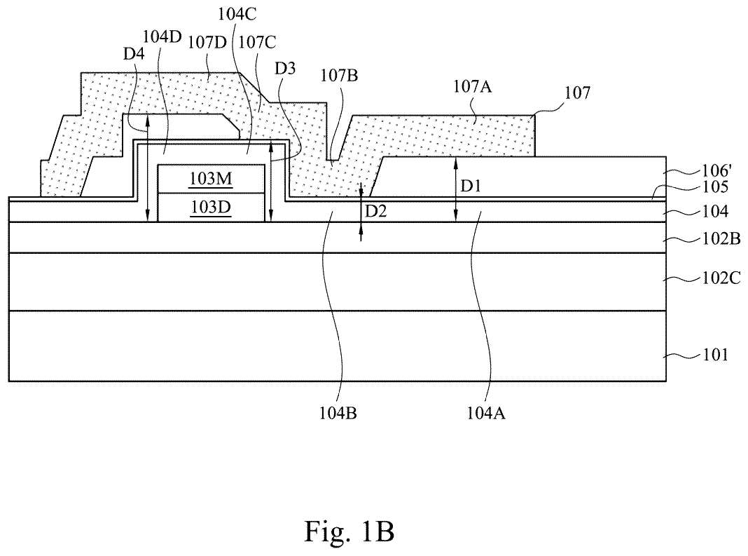

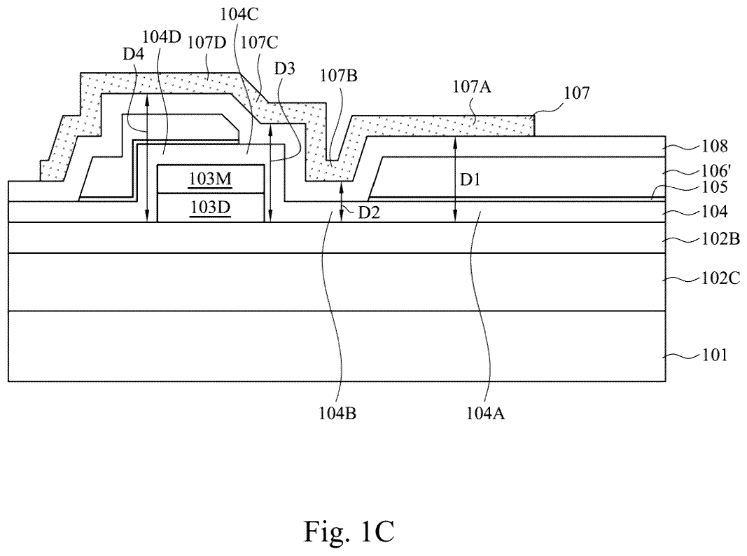

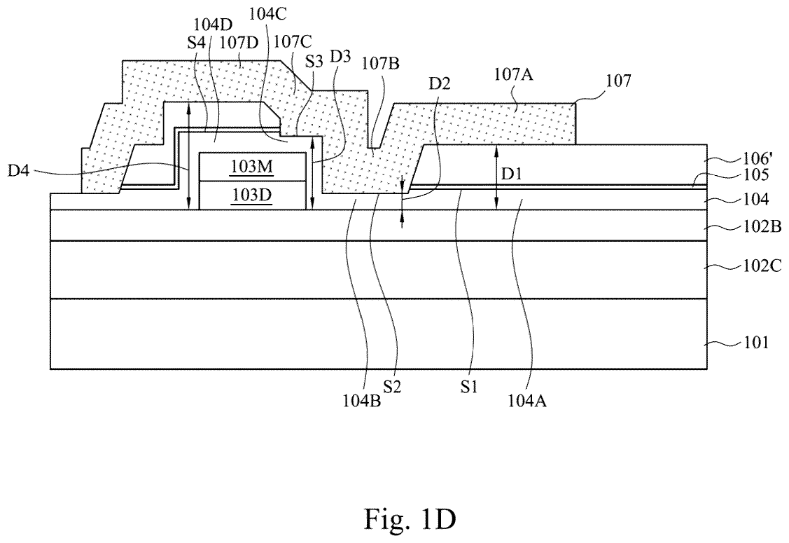

The disclosure provides a semiconductor structure in FIGS. 1A to 1D, including a gate structure 103 on a semiconductor layer 102 on a substrate 101, a first dielectric layer 104, an etch stop layer 105, and a second dielectric layer 106′ on the etch stop layer 105, and a field plate 107. The first dielectric layer 104 extends continuously on the gate structure 103 and the semiconductor layer 102 and includes a first portion 104A, a second portion 104B, a third portion 104C, and a fourth portion 104D. The first portion 104A and the second portion 104B are beside a same side of the gate structure 103, and the third portion 104C and the fourth portion 104D are on an upper surface of the gate structure 103. The etch stop layer 105 is on the first portion 104A and the fourth portion 104D and may also be on the second portion 104B and the third portion 104C (see FIG. 1B). A projection of the second dielectric layer 106′ on the substrate 101 overlaps a projection of the first portion 104A and the fourth portion 104D on the substrate 101 but does not overlap a projection of the second portion 104B and the third portion 104C on the substrate 101. The field plate 107 includes a first field plate portion 107A on the second dielectric layer 106′, a second field plate portion 107B and a third field plate portion 107C respectively on the second portion 104B and the third portion 104C, and a fourth field plate portion 107D on the second dielectric layer 106′. A lower surface of the first field plate portion 107A, a lower surface of the second field plate portion 107B, a lower surface of the third field plate portion 107C, and a lower surface of the fourth field plate portion 107D to the semiconductor layer 102 are respectively a first distance D1, a second distance D2, a third distance D3, and a fourth distance D4, the first distance D1 is larger than the second distance D2, and the third distance D3 is smaller than the fourth distance D4. In some embodiments, the first distance D1 is preferably from 500 Å to 5000 Å, e.g., 500 Å, 1000 Å, 2000 Å, 3000 Å, 4000 Å, or 5000 Å, the second distance D2 is preferably from 200 Å to 3500 Å, e.g. 200 Å, 500 Å, 1000 Å, 1500 Å, 2500 Å, or 3500 Å, the third distance D3 is preferably from 1800 Å to 6200 Å, e.g. 1800 Å, 2500 Å, 3500 Å, 4500 Å, 5500 Å, or 6200 Å, and the fourth distance D4 is preferably from 2100 Å to 7700 Å, e.g. 2100 Å, 3000 Å, 4000 Å, 5000 Å, 6000 Å, 6500 Å, or 7700 Å.

The substrate 101 may be any suitable semiconductor substrate and include any suitable semiconductor element, compound, and/or alloy, e.g., C, Si, Ge, SiC, BN, AlN, GaN, GaP, GaAs, InP, InAs, InSb, ZnO, SiGe, AlGaAs, InGaAs, InGaP, AlInAs, GaAsP, AlGaN, InGaN, AlGaInP, or combinations thereof. In some embodiments, the substrate 101 may include any suitable active component (e.g., diode, etc.), passive component (e.g., resistor, capacitor, etc.), wire, or combinations thereof, which is not drawn.

The semiconductor layer 102 includes a channel layer 102C and a barrier layer 102B on the channel layer 102C. The channel layer 102C makes carriers flow between the source and the drain which are not drawn for the simplify of the figures although the semiconductor structure includes the source structure and the drain structure on the semiconductor layer 102 and the gate structure 103 and the field plate 107 are between the source structure and the drain structure. The barrier layer 102B facilitates the formation of a high concentration of two-dimensional electron gas (2DEG) in the channel layer 102C to have high electron mobility and low resistance. In some embodiments, the channel layer 102C includes epitaxial gallium nitride. In some embodiments, the barrier layer 102B includes AlGaN.

The gate structure 103 controls the flow of carriers in the channel layer 102C. In some embodiments, the gate structure 103 includes a doped layer 103D and a metal layer 103M on the doped layer 103D. The doped layer 103D can be doped with an N-type dopant (e.g., C, Si, Ge, Sn, or analogs thereof) or a P-type dopant (e.g., Be, Mg, Ga, Sr, or analogs thereof) according to the requirements, for example, the doped layer 103D including GaN doped with the N-type dopant or the P-type dopant. The metal layer 103M can be any suitable electrode metal.

The first dielectric layer 104 extends continuously on the gate structure 103 and the semiconductor layer 102 to provide insulation. In some embodiments, the first dielectric layer 104 directly contacts the semiconductor layer 102 and the gate structure 103. For clarity, the first dielectric layer 104 includes the first portion 104A, the second portion 104B, the third portion 104C, and the fourth portion 104D. The combination of the first portion 104A and the fourth portion 104D and the combination of the second portion 104B and the third portion 104C respectively overlap and offset with the second dielectric layer 106′ in the direction vertical to the surface of the substrate 101. In some embodiments, the second portion 104B is closer to the gate structure 103 than the first portion 104A, and the third portion 104C is closer to the first portion 104A and the second portion 104B than the fourth portion 104D. In some embodiments, in addition to covering the semiconductor layer 102, a portion of the first dielectric layer 104 including the second portion 104B and the third portion 104C also continuously covers a portion of the upper surface and a side surface of the gate structure 103, and at least a portion of the gate structure 103 is not covered by the second dielectric layer 106′. In some embodiments, the first dielectric layer 104 includes SiO₂, Si₃N₄, SiON, or combinations thereof.

The etch stop layer 105 is on the first dielectric layer 104 and has a portion on the gate structure 103 to effectively control the etching depth when forming the semiconductor structure. For example, the etching can be stopped or paused until reaching the etch stop layer 105 to ensure that the material to be etched is removed completely without remaining the residue and to avoid excessively etching the material under the etch stop layer 105. The etch stop layer 105 avoids unintended residues and/or defects in the semiconductor structure that could affect the operation of the semiconductor structure. In some embodiments, the etch stop layer 105 includes AlN, Al₂O₃, SiN, or combinations thereof. In some embodiments, a thickness of the etch stop layer 105 is preferably from 20 Å to 100 Å, e.g., 20 Å, 40 Å, 60 Å, 80 Å, or 100 Å.

The second dielectric layer 106′ is on the first portion 104A and the fourth portion 104D and has a portion on the gate structure 103. The second dielectric layer 106′ does not cover the second portion 104B and the third portion 104C. The second dielectric layer 106′ is vertically separated from the first dielectric layer 104 by the etch stop layer 105. Since the second dielectric layer 106′ substantially completely offsets from the second portion 104B and the third portion 104C in a direction parallel to the surface of the substrate 101, the first dielectric layer 104 and the second dielectric layer 106′ together have a step-like shape. Since the etch stop layer 105 is between the first dielectric layer 104 and the second dielectric layer 106′, etching the second dielectric layer 106′ can be stopped or paused until reaching the etch stop layer 105 to make the height of the formed step-like shape of the first dielectric layer 104 and the second dielectric layer 106′ closer to the expectation (see the method below for details). In some embodiments, the second dielectric layer 106′ includes SiO₂, Si₃N₄, SiON, or combinations thereof.

The field plate 107 is on the step-like shape of the first dielectric layer 104 and the second dielectric layer 106′. The field plate 107 redistributes the electric field distribution around the edge of the gate structure 103 to effectively reduce the peak value of the electric field to avoid the occurrence of a breakdown voltage caused by an excessively high peak value of the electric field peak (i.e., the semiconductor structure of the disclosure can have a high breakdown voltage). Since the field plate 107 on the step-like shape also has the step-like shape, the field plate 107 gradually redistributes the electric field distribution to significantly increase the breakdown voltage of the semiconductor structure. It is not necessary to increase the breakdown voltage of the semiconductor structure by increasing the distance between the gate structure 103 and the source structure and/or the drain structure. In some embodiments, the field plate 107 includes TiN, Ti, AlCu, Al, AlSi, or combinations thereof.

In some embodiments, the field plate 107 extends continuously on the first dielectric layer 104 and the second dielectric layer 106′. In some embodiments, the field plate 107 has a substantially uniform thickness, so an upper surface of the field plate 107 also has a step-like shape similar to that of the first dielectric layer 104 and the second dielectric layer 106′. In some embodiments, the field plate 107 is separated from the gate structure 103 and the semiconductor layer 102 by the first dielectric layer 104. In some embodiments, the field plate 107 covers the upper surface and the side surface of the gate structure 103. In some embodiments, the field plate 107 completely covers the gate structure 103. In some embodiments, the lower surface of the first field plate portion 107A is higher than the upper surface of the gate structure 103, and the lower surface of the second field plate portion 107B is lower than the upper surface of the gate structure 103. In some embodiments, an upper surface of the first field plate portion 107A and an upper surface of the third field plate portion 107C are higher than an upper surface of the second field plate portion 107B. In some embodiments, an upper surface of the fourth field plate portion 107D is higher than the upper surface of the first field plate portion 107A and the upper surface of the third field plate portion 107C. In some embodiments, when the etch stop layer 105 does not cover the second portion 104B and the third portion 104C as shown in FIG. 1A, the field plate 107 directly contacts the second portion 104B and the third portion 104C. In some embodiments, the first field plate portion 107A and the second field plate portion 107B are beside a same side of the gate structure 103, and the third field plate portion 107C and the fourth field plate portion 107D are on the upper surface of the gate structure 103. In some embodiments, the first field plate portion 107A is farther away from the gate structure 103 than the second field plate portion 107B, and the third field plate portion 107C is closer to the first field plate portion 107A and the second field plate portion 107B than the fourth field plate portion 107D.

In some embodiments, as shown in FIG. 1C, the semiconductor structure includes a third dielectric layer 108 conformally on the first dielectric layer 104 and the second dielectric layer 106′, and the field plate 107 is on the third dielectric layer 108. When the semiconductor structure includes the third dielectric layer 108, the height of the field plate 107 can be adjusted more accurately according to the requirements to adjust the electric field distribution under the field plate 107 more accurately. In some embodiments, the third dielectric layer 108 continuously covers the first dielectric layer 104 and the second dielectric layer 106′ to provide a continuous and flat surface for the field plate 107 thereon. In some embodiments, the third dielectric layer 108 has a substantially uniform thickness. In some embodiments, the third dielectric layer 108 is not limited to the number shown in the figures and includes one or more layers. In some embodiments, the third dielectric layer 108 includes SiO₂, Si₃N₄, SiON, a high dielectric constant material (e.g., HfO₂), or combinations thereof.

In some embodiments, as shown in FIG. 1D, an upper surface S2 of the second portion 104B is lower than an upper surface S1 of the first portion 104A, and an upper surface S3 of the third portion 104C is lower than an upper surface S4 of the fourth portion 104D, so the height difference of the field plate 107 on the first dielectric layer 104 and the second dielectric layer 106′ can be adjusted more accurately according to the requirements to adjust the electric field distribution under the field plate 107 more accurately. In these embodiments, the etch stop layer 105 covers the first portion 104A and the fourth portion 104D but does not cover or exposes the second portion 104B and the third portion 104C.

The disclosure provides a method of forming the above semiconductor structure, including the following operations: forming the semiconductor layer 102 on the substrate 101, forming the gate structure 103 on the semiconductor layer 102, forming the first dielectric layer 104 on the gate structure 103 and the semiconductor layer 102, forming the etch stop layer 105 on the first dielectric layer 104, forming the second dielectric layer 106 on the etch stop layer 105, in which the etch stop layer 105 separates the second dielectric layer 106 from the first dielectric layer 104; etching a portion of the second dielectric layer 106 to make an etching depth at least reach an upper surface of the etch stop layer 105 to form an opening 1060 in a remaining portion (i.e., the second dielectric layer 106′ in the figures) of the second dielectric layer 106, in which a portion of the upper surface of the gate structure 103 and the side surface of the gate structure 103 connected to the portion of the upper surface of the gate structure 103 are under the vertical projection of the opening 1060; and forming the field plate 107 on the second dielectric layer 106′ and the opening 1060.

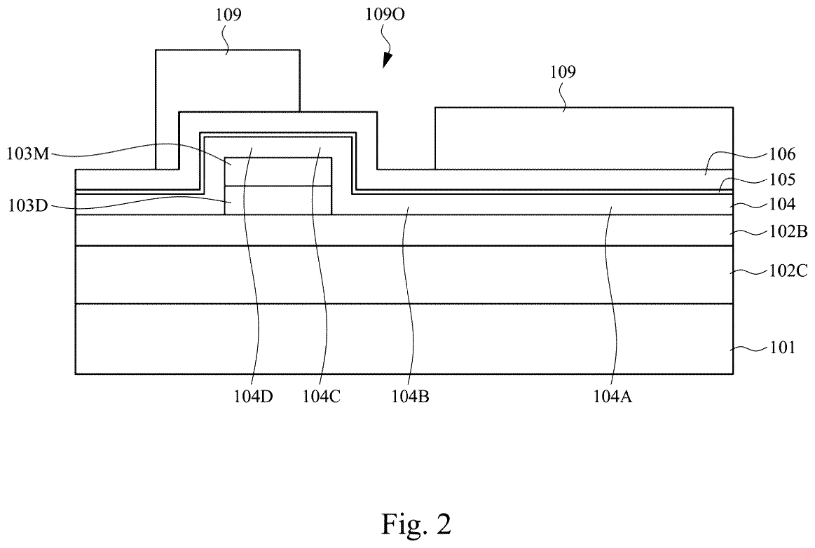

In FIG. 2, the gate structure 103 is formed on the semiconductor layer 102 on the substrate 101, and the first dielectric layer 104, the etch stop layer 105, and the second dielectric layer 106 are formed on the gate structure 103 and the semiconductor layer 102. The method of forming the gate structure 103, the first dielectric layer 104, the etch stop layer 105, and the second dielectric layer 106 may include any suitable method, e.g., a chemical vapor deposition. In some embodiments, forming the gate structure 103 includes forming the doped layer 103D and the metal layer 103M formed on the doped layer 103D, and forming the semiconductor layer 102 includes forming the channel layer 102C and the barrier layer 102B formed on the channel layer 102C. In some embodiments, the method further includes forming the source structure and the drain structure on the semiconductor layer 102 before forming the first dielectric layer 104, the etch stop layer 105, and the second dielectric layer 106.

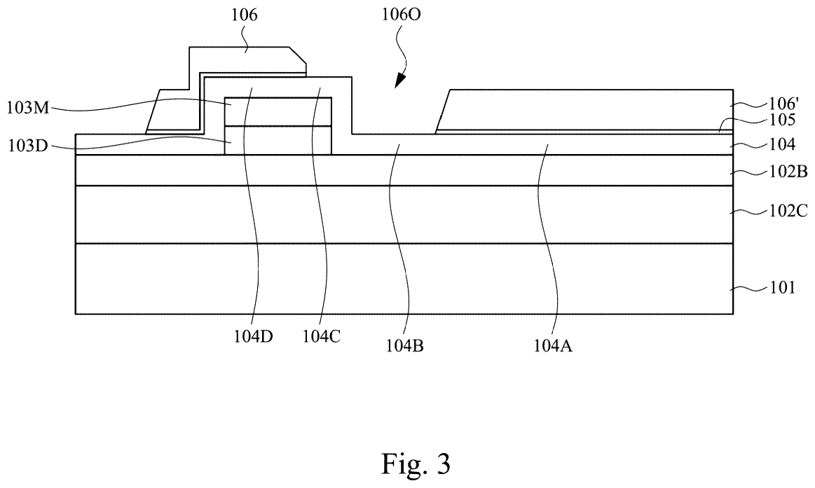

A photoresist layer 109 is formed on the second dielectric layer 106 to be a mask to etch a portion of the second dielectric layer 106 to form the patterned second dielectric layer 106′ shown in FIG. 3. The second dielectric layer 106′ patterned by the photoresist layer 109 forms the step-like shape together with the first dielectric layer 104, and the field plate 107 formed on such step-like shape correspondingly has the step-like shape. In detail, the photoresist layer 109 overlaps the first portion 104A and the fourth portion 104D, and the opening 1090 overlaps the second portion 104B and the third portion 104C. The portion of the second dielectric layer 106 exposed by the opening 1090 is etched by any suitable etching method, so the patterned second dielectric layer 106′ has the opening 1060 exposing the second portion 104B and the third portion 104C. In some embodiments, a suitable etching method includes a wet etching (e.g., using an etchant including HF, buffered oxide etch (BOE), H₃PO₄, or combinations thereof) or a dry etching (e.g., using an etching plasma gas including Cl₂; a combination of HCl and Cl₂, a combination of BCl₃ and SF₆, a combination of S₂F₂ and C₂F₆; C₃F₈; C₄F₈; C₅F₈; a combination of C₄F₆, NF₃, CHF₃, CH₂F₂, CH₃F, SiF₄, C₃F₈, and CCl₂F₂; or combinations thereof). In some embodiments, the etching depth at least reaches the upper surface of the etch stop layer 105 to ensure that the exposed portion of the second dielectric layer 106 is removed completely. The etch stop layer 105 also prevents the first dielectric layer 104 from being over-etched. In some embodiments, after the etching is paused when reaching the etch stop layer 105, the etching can continue to etch the etch stop layer 105 to remove the etch stop layer 105 in the opening 1060. In some embodiments, after etching the etch stop layer 105 in the opening 1060, exposed upper portions of the second portion 104B and the third portion 104C below the opening 1060 can be etched further to make the upper surfaces of the remained lower portions of the second portion 104B and the third portion 104C in the opening 1060 respectively lower than the upper surfaces of the first portion 104A and the fourth portion 104D outside the opening 1060 and under the second dielectric layer 106′. In some embodiments, the thicknesses of the upper portions of the second portion 104B and the third portion 104C before the etching are independently preferably from 50 Å to 500 Å, e.g., 50 Å, 100 Å, 200 Å, 300 Å, 400 Å, or 500 Å, and the thicknesses of the remained lower portions of the second portion 104B and the third portion 104C after the etching are independently preferably from 150 Å to 3400 Å, e.g. 150 Å, 500 Å, 1000 Å, 2000 Å, 3000 Å, or 3400 Å. In some embodiments, etching the etch stop layer 105 is performed by a wet etching process (e.g., using an etchant including a diluted HF, BOE, or a combination thereof), and etching the first dielectric layer 104 is performed by a dry etching process. In some embodiments, etching the etch stop layer 105 and the first dielectric layer 104 is performed by a single continuous wet etching process (e.g., using an etchant including a diluted HF, BOE, or a combination thereof).

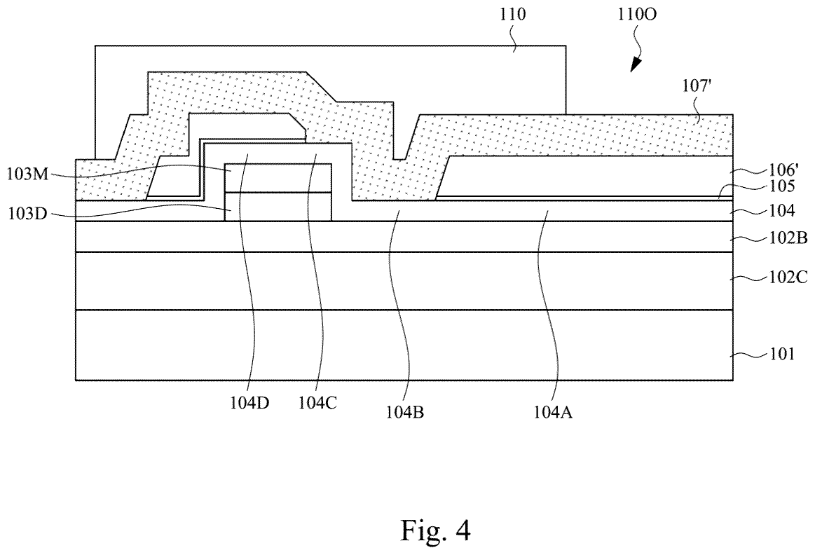

The field plate 107 is formed on the second dielectric layer 106′ and the opening 1060 to form the semiconductor structure as shown in FIG. 1A, FIG. 1B, or FIG. 1D, or in some embodiments, the third dielectric layer 108 is formed on the second dielectric layer 106′ and the opening 1060, and the field plate 107 is formed on the third dielectric layer 108 to form the semiconductor structure as shown in FIG. 1C. In some embodiments, when the embodiments include forming the third dielectric layer 108, the first dielectric layer 104 may not be etched, so the upper surface of the second portion 104B is substantially aligned with the upper surface of the first portion 104A, and the upper surface of the third portion 104C is substantially aligned with the upper surface of the fourth portion 104D. In some embodiments, as shown in FIG. 4, forming the field plate 107 includes depositing a field plate material 107′ continuously extending on the first dielectric layer 104 and the second dielectric layer 106′, and etching an edge portion of the field plate material 107′ to form the field plate 107. In some embodiments, the field plate material 107′ is patterned by forming a photoresist layer 110 on the field plate material 107′ as a mask to form the field plate 107 shown in FIGS. 1A to 1D, in which an opening 1100 of the photoresist layer 110 exposes the edge portion of the field plate material 107′ to be etched.

The semiconductor structure of the disclosure and the semiconductor structure formed by the method of the disclosure have high breakdown voltages to reduce current leakage. Moreover, the semiconductor structure has high electron mobility and good thermal stability. The semiconductor structure in the disclosure can be used not only for high electron mobility transistors (HEMTs) but also for high-power semiconductor components. With the help of the step-like shape of the first dielectric layer and the second dielectric layer formed with the etch stop layer between the first dielectric layer and the second dielectric layer, the height of the step-like shape is closer to the expectation, and the unexpected etching residue remained on the step-like shape is avoided. The field plate has more desirable height difference along the step-like shape to significantly increase the breakdown voltage and precisely adjust the charge distribution. The height difference of the step-like shape can also be adjusted in more detail by adding the third dielectric layer or etching an upper portion of a portion of the first dielectric layer. The continuously extending field plate with the height difference is formed by a single patterned process, thereby simplifying the process, improving the efficiency, and avoiding the damage to the field plate compared with forming the field plate in multiple steps.

What is claimed is:

1. A semiconductor structure, comprising:
a substrate;
a semiconductor layer on the substrate;
a gate structure on the semiconductor layer;
a first dielectric layer continuously extending on the gate structure and the semiconductor layer, wherein the first dielectric layer comprises a first portion, a second portion, a third portion, and a fourth portion, and the third portion and the fourth portion are on an upper surface of the gate structure;
an etch stop layer on at least the first portion and the fourth portion of the first dielectric layer;
a second dielectric layer on the etch stop layer; and
a field plate comprising a first field plate portion on the second dielectric layer, a second field plate portion and a third field plate portion respectively on the second portion and the third portion of the first dielectric layer, and a fourth field plate portion on the second dielectric layer, wherein a first distance between a lower surface of the first field plate portion and the semiconductor layer is larger than a second distance between a lower surface of the second field plate portion and the semiconductor layer, and a third distance between a lower surface of the third field plate portion and the semiconductor layer is smaller than a fourth distance between a lower surface of the fourth field plate portion and the semiconductor layer.

2. The semiconductor structure of claim 1, wherein the field plate extends continuously on the first dielectric layer and the second dielectric layer.

3. The semiconductor structure of claim 1, wherein a projection of the second dielectric layer on the substrate along a vertical direction of the substrate overlaps with a projection of the first portion and the fourth portion of the first dielectric layer on the substrate along the vertical direction of the substrate, and the projection of the second dielectric layer on the substrate along the vertical direction of the substrate does not overlap with a projection of the second portion and the third portion of the first dielectric layer on the substrate along the vertical direction of the substrate.

4. The semiconductor structure of claim 1, wherein the first field plate portion and the second field plate portion are beside a same side of the gate structure, and the second field plate portion is closer to the gate structure than the first field plate portion.

5. The semiconductor structure of claim 4, wherein the third field plate portion is closer to the first field plate portion and the second field plate portion than the fourth field plate portion.

6. The semiconductor structure of claim 1, further comprising a third dielectric layer on the first dielectric layer and the second dielectric layer, wherein the field plate is on the third dielectric layer.

7. The semiconductor structure of claim 1, wherein an upper surface of the second portion of the first dielectric layer is lower than an upper surface of the first portion of the first dielectric layer, and an upper surface of the third portion of the first dielectric layer is lower than an upper surface of the fourth portion of the first dielectric layer.

8. A method of forming a semiconductor structure, comprising:
forming a gate structure on a semiconductor layer on a substrate;
forming a first dielectric layer on the gate structure and the semiconductor layer;
forming an etch stop layer on the first dielectric layer;
forming a second dielectric layer on the etch stop layer, wherein the etch stop layer separates the second dielectric layer from the first dielectric layer;
etching a portion of the second dielectric layer to make an etching depth at least reach an upper surface of the etch stop layer to form an opening in a remaining portion of the second dielectric layer, wherein a portion of an upper surface of the gate structure and a side surface of the gate structure connected to the portion of the upper surface of the gate structure are under the opening; and
forming a field plate on the second dielectric layer and the opening.

9. The method of claim 8, further comprising etching a portion of the first dielectric layer below the opening to make an upper surface of the portion of the first dielectric layer below the opening is lower than an upper surface of a portion of the first dielectric layer below the second dielectric layer.

10. The method of claim 8, further comprising conformally forming a third dielectric layer on the second dielectric layer and the opening before forming the field plate.
